(19) United States
(12) Patent Application Publication
(10) Pub. No.: US 2008/0150778 A1
(43) Pub. Date: Jun. 26, 2008

(54) Digital Analog Converter System

(75) Inventor: Martin Hiddink, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/814,495

(22) PCT Filed: Jan. 20, 2006
(86) PCT No.: PCT/IB2006/050220

§ 371 Date: Jul. 23, 2007

(30) Foreign Application Priority Data
Jan. 26, 2005 (EP) 05100480.2

(51) Int. Cl. H03M 1/66

(52) U.S. Cl. 341/145

(57) ABSTRACT

A digital to analog converter system comprises an input circuit (3) which converts, during a sequence of corresponding time periods (Ti), a digital input signal (IS) having more than n bit into a sequence of n-bit digital input sub-signals (DS). An n-bit digital to analog converter (1) sequentially converts the digital input sub-signals (DS) into a sequence of analog output sub-signals (VD). A signal storage circuit (2) stores analog output sub-signals of the sequence of analog output sub-signals (VD) to obtain the analog output voltage (VO) as a combination of the sequence of analog sub-output signals (VD).

The invention relates to a digital to analog converter system, a method of converting a digital input signal (IS) into an analog output signal, a data driver for supplying analog data signals to data electrodes of a matrix display, a display device, and a display apparatus comprising a display device.

US 2004/0032637 discloses a circuit for driving electro-optical elements of an electro-optical display. Pixel driving chips include a plurality of pixel circuits; each one drives a corresponding organic EL element. A digital to analog converting circuit, further referred to as the D/A converting circuit, has D/A converters corresponding to the number of data lines which extend in the column direction. These D/A converters are elucidated with respect to FIG. 13 of this prior art. The now following references are to be found in this FIG. 13 of the prior art. The D/A converters comprise current mirrors Trc1 to Trc6 which generate currents Ia to If which have a ratio of 1:2:4:8:16:32. The absolute values of these currents depend on a reference current Ir. The digital input data Xd is supplied to switches Ts1 to Ts6. Dependent on the bit values of the word of the digital input data Xd, the switches Ts1 to Ts6 are open or closed. The least significant bit of the word is supplied to the switch associated with the smallest current Ia, the most significant bit of the word is supplied to the switch associated with the largest current If. The currents Ia to If for the closed switches Ts1 to Ts6 are supplied to the data line DL. Thus, the total current supplied to the data line depends on the bit values of the word. Such a D/A converter, further also referred to as DAC, converts an n bit word into 2ⁿ analog levels.

It is an object of the invention to provide a D/A converter system which is able to convert a p bit digital word into an analog output signal having the corresponding required number of analog levels, although a DAC is used for converting a word which has less than p bits into a corresponding number of analog levels which is lower than the number of analog levels of the analog output signal of the DAC system.

A first aspect of the invention provides a digital to analog converter system as claimed in claim 1. A second aspect of the invention provides a method of converting a digital input signal (IS) into an analog output signal as claimed in claim 13. A third aspect of the invention provides a data driver for supplying analog data signals to data electrodes of a matrix display as claimed in claim 14. A fourth aspect of the invention provides a display device as claimed in claim 15. A fifth aspect of the invention provides a display apparatus comprising a display device of claim 16. Advantageous embodiments are defined in the dependent claims.

The digital to analog converter system converts an input digital signal, which comprises p-bit words, into an analog output signal. The DAC system comprises a DAC, which converts a digital input sub-signal, which has words with less than p bits into an analog output sub-signal. If the DAC is able to convert n-bit words, wherein n is smaller than p, the analog output sub-signal has a 2ⁿ analog levels. A controller controls an input circuit to convert the p-bit digital input signal into a sequence of n-bit digital input sub-signals which are sequentially supplied to the DAC to obtain a sequence of analog output sub-signals during a sequence of corresponding time periods. A signal storage circuit stores the analog output sub-signals until a last one of the time periods to obtain the analog output voltage as a combination of the analog output sub-signals.

Thus, instead of supplying a single p-bit word to the analog converter, the input signal is now converted in a sequence of n-bit words, which represent the digital input sub-signals. The resulting sequence of analog output sub-voltages is stored until the last time period such that all the analog output sub-voltages of the sequence are available to determine the output voltage of the system.

In an embodiment in accordance with the invention as claimed in claim 2, the DAC has a same output signal range during each of the time periods. The output signal range of the DAC is the difference between the analog output voltage for a digital input signal with a minimum value (all bits of the digital word are zero) and a digital input signal with the maximum value (all bits of the digital word are one). Thus, by way of example only, if the p bit digital input signal is split in two digital input sub-signals of n bits each, two analog output sub-signals are obtained each with the same analog levels if the same digital sub-signals are applied. The first analog output sub-signal generated during the first time period is stored until the second time period wherein the second analog output sub-signal is generated. The analog output signal may be obtained by adding the first and the second analog output sub-signal. Now, by using the same single p-bit DAC an analog output signal is generated which has 2^{p+1} levels. It is thus not required that the DAC system provides 2ⁿ levels. Alternatively, it is possible to add more than two analog output sub-signals if the digital input signal is split into more than two digital input sub-signals. Or, the analog signals may be multiplied with a factor before they are summed or subtracted.

In an embodiment in accordance with the invention as claimed in claim 3, the digital to analog converter system further comprises a range circuit which supplies a range signal to a range input of the DAC. The range signal determines a signal range of the analog output sub-signal. The controller controls the range circuit to supply a sequence of range signals, one for each time period, to the DAC. Now, the range signals may be different in different time periods. This provides more flexibility in reaching a required spacing of the analog sub-levels.

In an embodiment in accordance with the invention as claimed in claim 4, at least one of the signal range determining signals of the sequence is different than the other to obtain at least two different signal ranges of the analog output sub-signals of different time periods. For example, if only two time periods are present, the range during the one time period may be selected to be smaller than the range during the other time period. Now, during the first time period the least significant bits of the p-bit word may be used while during the second time period the most significant bits are used. The summing of the two analog output sub-signals generated during the first and the second period in time provides the analog output signal with 2²ⁿ levels when the two ranges have a ratio of 2ⁿ and p equals 2n.

In an embodiment in accordance with the invention as claimed in claim 5, the DAC is a multiplying DAC which as such is well known and which has a multiplier input, which is the range determining input.

In an embodiment in accordance with the invention as claimed in claim 6, the signal storage circuit comprises at least one capacitor to store the analog output sub-signals.

In an embodiment in accordance with the invention as claimed in claim 7, the analog output sub-signals are currents, which are sequentially generated during the time periods. Each of the currents may be fed to a same capacitor, preferably each during a same predetermined period of time during its corresponding time period. The voltage across the capacitor after the last period of time is the output signal of the system. Alternatively, it is possible to select the integrating time for the currents generated during different periods to be different to introduce different weight factors.

In an embodiment in accordance with the invention as claimed in claim 8, the analog output sub-signals are voltages which each may be stored on a separate capacitor. The voltages on the capacitors are combined by a circuit which for example comprises opamps, or which comprises switches to arrange the capacitors in series. Alternatively, it is possible to add the output sub-voltages across a same capacitor.

In an embodiment in accordance with the invention as claimed in claim 9, the digital to analog converter system converts the digital input signal to the analog output signal in two steps. Thus, the sequence of time periods comprises a first and second time period. The signal storage circuit comprises a switch and a capacitor. The switch and the capacitor are arranged such that the first analog output sub-signal generated during the first period in time is stored in the capacitor. Now, during the second period in time both the first analog output sub-signal and the second analog output sub-signal are available to generate the analog output signal.

Such a two step approach is relatively efficient because only a single signal has to be stored and the time required to convert the digital input signal into the analog output signal is minimally enlarged.

In an embodiment in accordance with the invention as claimed in claim 12, a ratio between the first output signal range and the second output signal range is 2ⁿ. This choice allows converting a 2n-bit digital input word into 2²ⁿ analog level with an n-bit DAC.

These and other aspects of the invention are apparent from and will be elucidated with reference to the embodiments described hereinafter.

In the drawings:

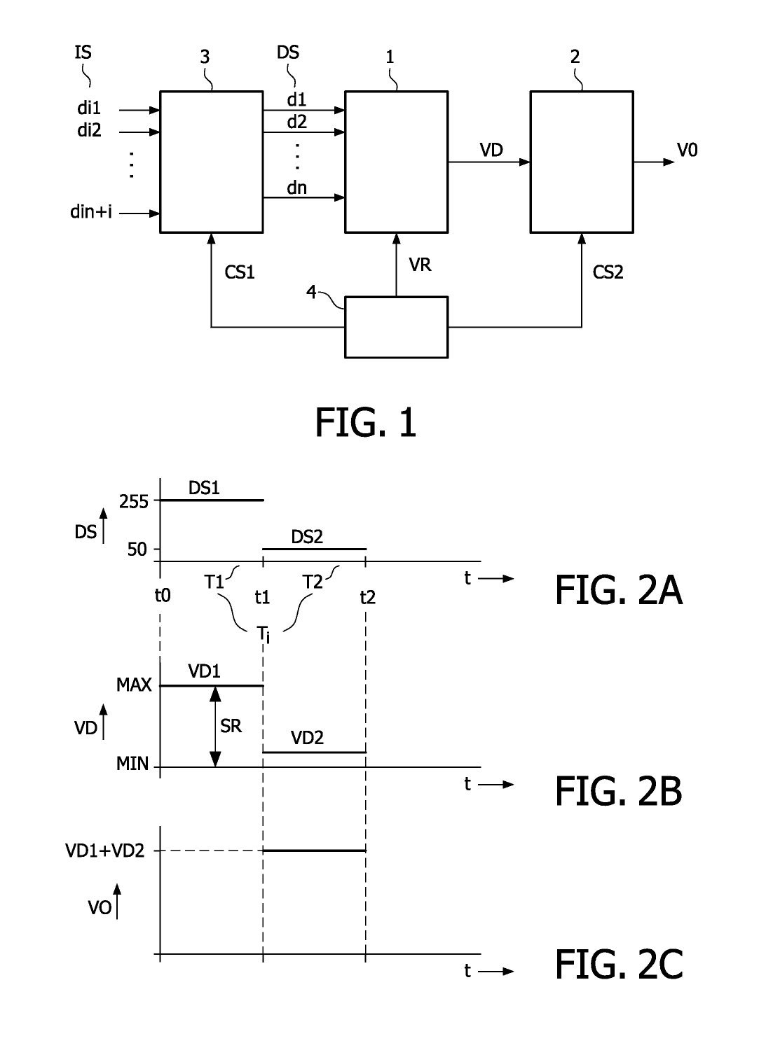

FIG. 1 shows a block diagram of the digital to analog converter system in accordance with the invention,

FIGS. 2A, 2B and 2C show signals for elucidating the operation of the digital to analog converter system of FIG. 1,

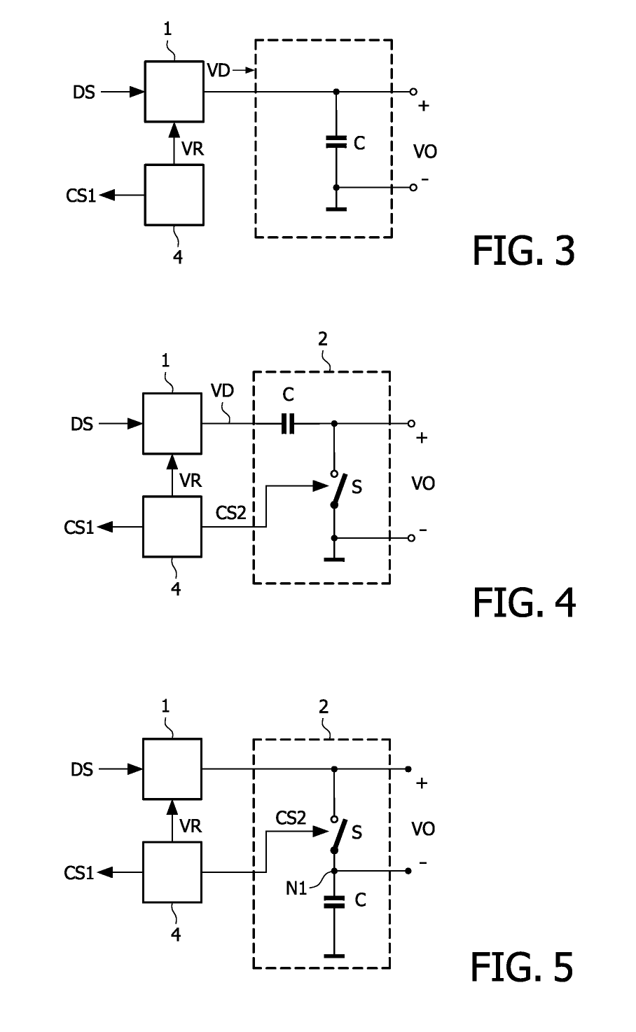

FIG. 3 shows a circuit diagram of an embodiment of the digital to analog converter system,

FIG. 4 shows a circuit diagram of an embodiment of the digital to analog converter system,

FIG. 5 shows a circuit diagram of an embodiment of the digital to analog converter system,

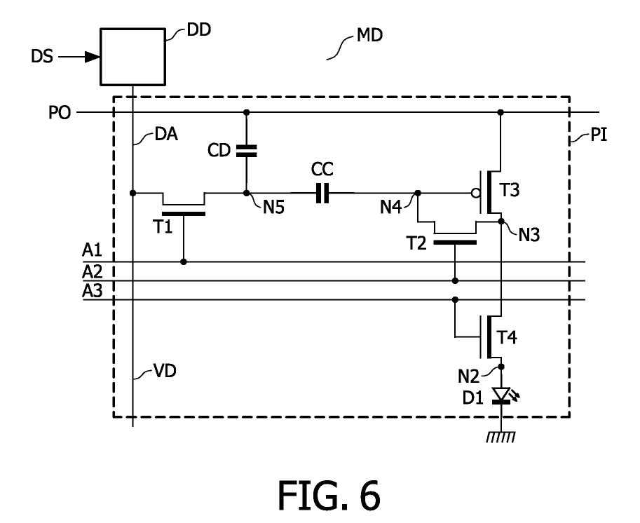

FIG. 6 shows part of a (polymer) OLED display, and

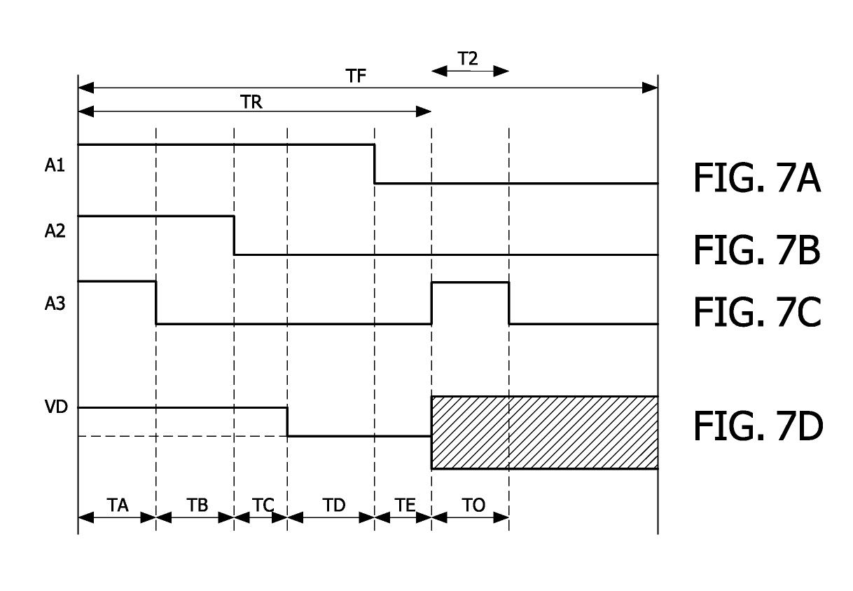

FIGS. 7A to 7D show waveforms for elucidating the operation of the (polymer) OLED display shown in FIG. 6.

FIG. 1 shows a block diagram of the digital to analog converter system in accordance with the invention. The digital to analog converter system comprises an input circuit 3, an n-bit DAC, a signal storage circuit 2 and a controller 4.

The input circuit 3 receives a digital input signal IS with words which have more bits than n bits. The DAC 1 is not able to convert the digital input signal IS into an analog signal having all the possible analog signal levels indicated by the digital input signal IS. By way of example, FIG. 1 shows a digital input signal IS which has (n+i)-bit words. The bits of the (n+i)-bit words are indicated by di1 to din+i. The input circuit 3 converts the digital input signal IS into a sequence of n-bit words which are supplied to the DAC 1 during a sequence of time periods Ti (see FIG. 2A to 2C). These n-bit words are referred to as the digital input sub-signals DS. The bits of the digital input sub-signals DS are indicated by d1 to dn. The number of digital input sub-signals DS of a sequence depend on the difference of the number of bits in the words of the digital input signal IS and the digital input sub-signals DS, and on the selection of the signal VR supplied to the DAC 1 during the different time periods Ti of the sequence. For example, if VR is identical during each one of the different time periods, the number of analog output levels becomes the number of time periods times 2ⁿ.

Each of the n-bit words are converted by the DAC 1 with full resolution into a sequence of analog signals which are referred to as the analog output sub-signals VD. The output voltage range of the DAC 1 is determined by the signal VR which is further also referred to as the range signal VR. The output voltage range of the DAC1 is the range of levels of the analog output sub-signal VD. These extreme values of this range are determined by selecting the minimum and maximum value of the digital input sub-signal DS. For example, if an 8 bit DAC is used, the minimum value of the digital input sub-signal DS is 0 and the maximum value is 255. The range signal VR determines the lower and upper limits of the analog output sub-signal VD. The range signal VR may be a single reference signal controlling the amplitude of the analog output sub-signal VD, or may comprise two levels indicating the lower and upper levels separately. If the D/A converter comprises a resistor ladder, these two levels may be the voltage levels supplied to the input terminals of the resistor ladder. The range signal VR may be different during different time periods of the sequence. For example, if the sequence comprises two time periods, it is possible to convert a digital input signal IS with 2n-bit words with an n-bit DAC 1 if the ratio of the output voltage ranges of the DAC 1 is selected to be 2ⁿ. In fact the smallest range is now selected to subdivide a single bit level of the larger range in 2ⁿ-levels.

The signal storage circuit 2 receives the sequence of analog output sub-signals VD and stores the values generated during the time periods of the sequence at least until the last time period of the sequence. Now, all the analog output sub-signals VD are available and can be combined to obtain the analog output signal VO. For example, the analog output sub-signals VD may be added or subtracted, directly or with a weighting factor. Preferably, at least one capacitance is used to store the analog output sub-signals.

The controller 4 supplies a control signal CS1 to the input circuit 3, the range signal VR to the DAC 1, and, optionally, the control signal CS2 to the signal storage circuit 2. The control signal CS1 indicates to the input 3 when a sequence for converting a next digital input signal IS starts and when the time periods starts during which the digital input sub-signals DS have to be supplied to the DAC 1. The range signal VR is controlled to have the desired value during each of the time periods to obtain the desired output range of the DAC 1 during each of the time periods. The control signal CS2 indicates to the signal storage circuit when the analog output sub-signals VD are available and should be stored, and when all the values are available to be combined.

FIGS. 2A, 2B and 2C show signals for elucidating the operation of the digital to analog converter system of FIG. 1 for a two step sequence.

FIG. 2A shows the digital input sub-signals DS. At the instant t0, the digital input signal IS is available. During the period in time T1, which lasts from t0 to t1, the input circuit 3 supplies the n-bit first digital input sub-signal DS1 to the n-bit DAC 1. During the period in time T2, which lasts from t1 to t2, the input circuit 3 supplies the n-bit second input sub-signal DS2 to the DAC 1. The periods in time T1 and T2 are also referred to as Ti. In this example, it is assumed that the range signal VR is identical during all the periods in time Ti, and that an 8-bit DAC 1 is used. In such a system, it is possible to generate twice the number of levels which are generated by a conventional 8-bit DAC. In this example the digital value 305 is accurately converted to an analog level by the 8-bit DAC 1 by first converting the value 255 during the first period in time T1 and then converting the value 50 during the second period in time T2.

FIG. 2B shows the analog output sub-signals VD which during the first period in time T1 have the level VD1 corresponding to the digital value 255 and which during the second period in time T2 have the level VD2 corresponding to the digital value 50. When the digital value 255 is supplied to the DAC 1, the level of the analog output sub-voltage VD1 has the maximum level MAX. If the digital value 0 is supplied to the DAC 1, the level of the analog output sub-voltage VD1 would have been the minimal value MIN. The difference between the minimum value MIN and the maximum value MAX is the output range SR of the DAC 1.

FIG. 2C shows the analog output voltage VO which in this example is the addition of the levels of the analog output sub-signals VD1 and VD2.

Many alternative approaches are possible. For example, to increase the number of levels of the analog output signal VO, the range signal VR may differ during the different time periods T1 and T2. If even more analog levels are required, the sequence of converting the digital input signal IS into the analog output signal VO may comprise more than two time periods Ti. To guarantee a monotonous range of values if the linearity of the DAC 1 is not perfect, preferably always the same strategy is followed to determine the digital input sub-signals DS if bits change. For example, if the range signal is identical during the two time periods T1 and T2, the value 0 is converted during the second time period T2 as long as the digital input signal IS has a level not higher than 255. Preferably, the signals DS are selected such that a difference of one level in the signal IS results in a difference of one level in DS for only one of the two time periods.

FIG. 3 shows a circuit diagram of an embodiment of the digital to analog converter system. FIG. 3 shows an embodiment of the signal storage circuit 2. The DAC 1, which is identical to that shown in FIG. 1, receives the digital input sub-signals DS, the range signal VR and supplies the analog output sub-signals VD as currents. The controller 4 generates the control signal CS1 and the range signal VR in the same manner as shown in FIG. 1. The signal storage circuit 2 comprises a capacitor C which is arranged between the output of the DAC 1 and a reference level which may be ground. The output voltage VO is present across the capacitor C. Although the controller 4 now does not show the control signal CS2, in fact the voltage across the capacitor C has to be reset each cycle to start the charging with a well defined voltage across the capacitor. Therefore, a switch may be arranged in parallel with the capacitor C.

By way of example only, this system is elucidated if only two time periods Ti are present in a conversion sequence. During the first period in time T1, the digital input sub-signal DS has a value DS1 and the range signal VR has a value or level VR1. The analog output sub-signal VD is an amount of current VD1 which is supplied to the capacitor C during a predetermined period of time. The predetermined period of time may be the first period in time T1 or a sub-period thereof. The current VD1 is integrated by the capacitor C and gives rise to a corresponding voltage change across the capacitor C. The amount of current VD1 is determined by the value DS1 and by the range signal VR1. During the second period in time T2, the digital input sub-signal DS has a value DS2 and the range signal VR has a value or level VR2. The analog output sub-signal VD is an amount of current VD2 which is supplied to the capacitor C during a predetermined period of time. The predetermined period of time may be the second period in time T2 or a sub-period thereof. The current VD2 is integrated by the capacitor C and gives rise to a corresponding voltage change across the capacitor C. The amount of current VD2 is determined by the value DS2 and by the range signal VR2. At the end of the second period in time T2 the voltage across the capacitor C directly provides the output voltage VO.

FIG. 4 shows a circuit diagram of an embodiment of the digital to analog converter system. FIG. 4 shows an embodiment of the signal storage circuit 2. The DAC 1, which is identical to that shown in FIG. 1, receives the digital input sub-signals DS, the range signal VR and supplies the analog output sub-signals VD as voltages. The controller 4 generates the control signal CS1, CS2 and the range signal VR in the same manner as shown in FIG. 1. The signal storage circuit 2 comprises a capacitor C which is arranged between the output of the DAC 1 and the output of the system at which the analog output voltage VO is supplied. A switch S is arranged between the output of the system and a reference level which may be ground. The switch S is controlled by the control signal CS2. The output voltage VO is present across the switch S.

By way of example only, this system is elucidated if only two time periods Ti are present in a conversion sequence. During the first period in time T1, the switch S is closed, and the digital input sub-signal DS has a value DS1 and the range signal VR has a value or level VR1. The analog output sub-signal VD is the voltage level VD1 which is stored on the capacitor C. The level of the voltage VD1 is determined by the value DS1 and by the range signal VR1. During the second period in time T2, the switch S is open, and the digital input sub-signal DS has a value DS2 and the range signal VR has a value or level VR2. The analog output sub-signal VD is a voltage level VD2 which is supplied to the capacitor C which is arranged between the output of the DAC 1 and the output of the system. The output voltage VO is now the sum of the voltage level VD2 present at the output of the DAC 1 and the voltage level VD1 stored on the capacitor C. The level of the voltage VD2 is determined by the value DS2 and by the range signal VR2.

FIG. 5 shows a circuit diagram of an embodiment of the digital to analog converter system. FIG. 5 shows an embodiment of the signal storage circuit 2. The DAC 1, which is identical to that shown in FIG. 1, receives the digital input sub-signals DS, the range signal VR and supplies the analog output sub-signals VD as voltages. The controller 4 generates the control signal CS1, CS2 and the range signal VR in the same manner as shown in FIG. 1. The signal storage circuit 2 comprises a switch S which is arranged between the output of the DAC 1 and a node N1. The switch S is controlled by the control signal CS2. A capacitor C is arranged between the node N1 and a reference level which may be ground. The output of the DAC 1 is connected to one of the output terminals of the system. The output voltage VO is present across the switch S.

By way of example only, this system is elucidated if only two time periods Ti are present in a conversion sequence. During the first period in time T1, the switch S is closed, and the digital input sub-signal DS has a value DS1 and the range signal VR has a value or level VR1. The analog output sub-signal VD is the voltage level VD1 which is stored on the capacitor C. The level of the voltage VD1 is determined by the value DS1 and by the range signal VR1. During the second period in time T2, the switch S is open, and the digital input sub-signal DS has a value DS2 and the range signal VR has a value or level VR2. The analog output sub-signal VD is a voltage level VD2 which is supplied to one of the output terminal of the system. The level of the voltage VD2 is determined by the value DS2 and by the range signal VR2. The other output terminal of the system is connected to the node N1 at which the voltage level VD1 is present. The output voltage VO is now the difference of the voltage level VD2 present at the output of the DAC 1 and the voltage level VD1 stored on the capacitor C.

FIG. 6 shows part of an (polymer) OLED display. The OLED display MD comprises a data driver DD, a select driver (not shown), and a plurality of pixels PI of which only one is shown. The data driver DD receives for each digital input word a sequence of digital input sub-signals DS. The data driver DD comprises a DAC which converts the sequence of digital input sub-signals DS into a corresponding sequence of analog output voltages VD to the data line DA. The power line PO supplies a power supply voltage. The select or address lines A1, A2, A3 control the addressing sequence of the pixel. The pixel comprises an (polymer) OLED D1 with an anode connected to node N2 and a cathode connected to ground. A transistor T4 has a main current path arranged between the node N2 and a node N3, and a control input connected to the address line A3. A transistor T3 has a main current path arranged between the power line PO and the node N3, and a control input connected to a node N4. A transistor T2 has a main current path arranged between the nodes N3 and N4, and a control input connected to the address line A2. A capacitor CC is arranged between the nodes N4 and N5. A capacitor CD is arranged between the power line PO and the node N5. A transistor T1 has a main current path arranged between the data line DA and the node N5, and a control input connected to the address line A1. The operation of this pixel circuit is elucidated with respect to FIG. 7. It has to be noted that this pixel circuit as such is known from prior art, only its operation is different because different signals can be supplied during the different time periods Ti. It further has to be noted that the capacitor CC shown in FIG. 6 corresponds to the capacitor C shown in FIGS. 3 to 5, and the transistors T2 and T3 together form the switch S.

FIGS. 7A to 7D show waveforms for elucidating the operation of the pixel structure shown in FIG. 6. FIG. 7A shows the voltage on the address line A1. FIG. 7B shows the voltage on the address line A2. FIG. 7C shows the voltage on the address line A3. FIG. 7D shows the voltage VD on the data line DA. A row of pixels is addressed during a row period TR. The data voltages VD are supplied in parallel to the selected row of pixels. The frame period TF is the period in time available to address all the rows of pixels which should be updated. Usually, the frame period is the period in time required to address all the rows of pixels. During each row period TR five consecutive periods occur: the overdrive period TA, the correction period TB, the pre-address period TC, the address period TD, and the post address period TE.

During the overdrive period TA, all addressing lines A1, A2, A3 are high and the transistors T1, T2, T4, respectively, are conductive. The first data signal VD1 is applied as a dynamic reference. Now, this reference level (which is the first data signal VD1) is present at the node N5, and a relatively low voltage across the LED D1 is present at the node N4. Due to the low level at the node N4, also the drive transistor T3 is conductive.

During the correction period TB, the addressing line A3 is made low, and all other signals do not change. The node N5 is kept on the reference level VD1 while the level on the node N4 rises due to the conductive transistors T3 and T2 which supply a current to the capacitor CC. At the instant the voltage on the node N4 reaches the voltage on the power line minus the threshold voltage of the drive transistor T3, the drive transistor T3 stops conducting. Thus now, the voltage stored on the capacitor CC equals the reference voltage VD1 at node N5 minus the voltage at node N4. During the pre-address period TC, the address line A2 gets a low level and the transistor T2 is switched off.

During the address period TD, the second data signal VD2 on the data line DA is applied. This data level is forwarded to the node N5. Consequently, the voltage on the node N4 is now the power line voltage minus the threshold voltage plus the difference between the data voltages VD2 and VD1. The drive voltage VD2−VD1 of the drive transistor T3 is thus compensated for the threshold voltage of the drive transistor T3. During the post address period TE, the address line A1 gets a low level and the transistor T1 disconnects the pixel from the data line DA. The second data voltage VD2 is stored on the capacitor CD. The address line A3 is made high during the light generating period TO to generate a current through the LED D1 which is determined by the data voltages VD1 and VD2 stored on the capacitor CC and CD, and which is compensated for variations of the threshold voltage of the drive transistor T3.

It has to be noted that the capacitor CC in a first period of time (T1 in FIG. 2A) stores the first analog output sub-signal VD1 at node N5 as the black level, and that in the second period of time (T2 in FIG. 2A) feeds the second analog output sub-signal VD2 to one end of the capacitor CC and CD (at the node N5) such that the effective drive voltage at the other end of the capacitor CC (at the node N4) will become equal to VD2−VD1. This voltage difference is fed to T3, which sets the current through the OLED to determine the luminance of the OLED.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. A digital to analog converter system comprising
an input circuit (3) for converting, during a sequence of corresponding time periods (Ti), an p bit digital input signal (IS) into a sequence of digital input sub-signals (DS) having less than p bit,
a digital to analog converter (1) for sequentially converting the digital input sub-signals (DS) into a sequence of analog output sub-signals (VD), and
a signal storage circuit (2) for storing analog output sub-signals of the sequence of analog output sub-signals (VD) to obtain the analog output voltage (VO) as a combination of the sequence of analog sub-output signals (VD).

2. A digital to analog converter system as claimed in claim 1, wherein the digital to analog converter (1) has a same output signal range (SR) during each one of the time periods (Ti).

3. A digital to analog converter system as claimed in claim 1, further comprising a controller (4) for supplying a sequence of range signals (VR), one for each one of the time periods (Ti), to the digital to analog converter (1) to determine respective signal ranges of the analog output sub-signals (VD).

4. A digital to analog converter system as claimed in claim 3, wherein at least two of the range signals of the sequence of range signals (VR) are different to obtain at least two different signal ranges of the corresponding analog output sub-signals (VD).

5. A digital to analog converter system as claimed in claim 1, wherein the digital to analog converter (1) is a multiplying digital to analog converter with a multiplier input for receiving the range signal (VR).

6. A digital to analog converter system as claimed in claim 1, wherein the signal storage circuit (2) comprises at least one capacitor (C) for storing the analog output sub-signals (VD).

7. A digital to analog converter system as claimed in claim 1, wherein the output sub-signals (VD) are output currents, and the signal storage circuit (2) integrates the output currents (10) in a capacitor (C).

8. A digital to analog converter system as claimed in claim 1, wherein the output sub-signals (VD) are output voltages, and the signal storage circuit (2) stores at least one of the output voltages (VD).

9. A digital to analog converter system as claimed in claim 1, wherein
the sequence of time periods (Ti) comprises a first time period (T1) and second time period (T2) to convert the digital input signal (IS) into the analog output signal (VO) in two steps,
the input circuit (3) is arranged for converting the digital input signal (IS) into a first digital input sub-signal (DS1) and a second digital input sub-signal (DS2), the first digital input sub-signal (DS1) being supplied to the digital to analog converter (1) to obtain a first analog output sub-signal (VD1) during the first time period (T1), and the second digital input sub-signal (DS2) being supplied to the digital to analog converter (1) to obtain a second analog output sub-signal (VD2) during the second time period (T2), wherein during the first time period (T1) the digital to analog converter (1) has a first output signal range, and during the second time period (T2) the digital to analog converter (1) has a second output signal range, and
the signal storage circuit (2) comprises a capacitor (C) and a switch (S) for storing the first analog output sub-signal (VD1) in the capacitor (C) during the first period in time.

10. A digital to analog converter system as claimed in claim 9, wherein the capacitor (C) is arranged between an output of the digital to analog converter (1) at which the analog output sub-signal (VD) is present and an output of the digital to analog converter system at which the analog output signal (VO) is present, and the switch (S) is arranged between the output of the digital to analog converter system and a reference voltage, wherein the controller (4) is arranged for closing the switch (S) during the first period in time (T1) and for opening the switch (S) during the second period in time (T2).

11. A digital to analog converter system as claimed in claim 9, wherein a series arrangement of the switch (S) and the capacitor (C) is arranged between an output of the digital to analog converter (1) at which the analog output sub-signal (VD) is present and a reference voltage, and wherein the controller (4) is arranged for closing the switch (S) during the first period in time (T1) and for opening the switch (S) during the second period in time (T2), the analog output voltage (VO) being a voltage across the switch (S) during the second period in time (T2).

12. A digital to analog converter system as claimed in claim 9, wherein the digital input sub-signals (DS) are p/2-bits words, and a ratio between the first output signal range and the second output signal range is 2ⁿ, wherein p=2n.

13. A method of converting a digital input signal (IS) into an analog output signal, the method comprises
converting (3), during a sequence of corresponding time periods (Ti), a n bit digital input signal (IS) into a sequence of digital input sub-signals (DS) having less than n bit,
sequentially converting (1) the digital input sub-signals (DS) into a sequence of analog output sub-signals (VD),
storing (2) analog output sub-signals of the sequence of analog output sub-signals (VD), and
obtaining (2) the analog output voltage (VO) as a combination of the sequence of analog sub-output signals (VD)

14. A system of a data driver (DD) and a matrix display (MD), wherein the data driver (DD) comprises an n-bit digital to analog converter (1) for receiving, during a sequence of corresponding time periods (Ti), a sequence of n-bit digital input signals (DS) to supply a corresponding sequence of analog data signals (VD) to data electrodes of the matrix display (MD) comprising pixels (PI), wherein the pixels (PI) comprise a signal storage circuit (CC, CD, T2, T3) for storing the analog data signals (VD) to obtain an analog output voltage (VO) as a combination of the sequence of analog sub-output signals (VD).

15. A display device comprising the data driver of claim 14.

16. A display apparatus comprising a display device of claim 15.
